(19) United States
(12) Patent Application Publication
(10) Pub. No.: US 2024/0282828 A1
(43) Pub. Date: Aug. 22, 2024

(54) SEMICONDUCTOR DEVICE AND MANUFACTURING METHOD THEREOF

(71) Applicant: Samsung Electronics Co., Ltd., Suwon-si (KR)

(72) Inventors: Youngwoo Kim, Suwon-si (KR); KYOUNGWOO LEE, Suwon-si (KR); MINCHAN GWAK, Suwon-si (KR); Gukhee Kim, Suwon-si (KR); SANGCHEOL NA, Suwon-si (KR); Anthony Dongick Lee, Suwon-si (KR)

(21) Appl. No.: 18/238,872

(22) Filed: Aug. 28, 2023

(30) Foreign Application Priority Data
Feb. 20, 2023 (KR) 10-2023-0022047

(51) Int. Cl. H01L 29/417; H01L 29/06; H01L 29/423; H01L 29/66; H01L 29/775; H01L 29/786

(52) U.S. Cl. CPC H01L 29/41733; H01L 29/0673; H01L 29/42392; H01L 29/66439; H01L 29/775; H01L 29/78696

(57) ABSTRACT

An embodiment provides a semiconductor device including a semiconductor substrate having first and second surfaces opposite each other, a channel pattern disposed on the first surface of the semiconductor substrate; source/drain patterns disposed on the first surface of the semiconductor substrate and disposed at both sides of the channel pattern; first and second etch stop films disposed on the first surface of the semiconductor substrate; a contact electrode electrically connected to the source/drain patterns; a lower wire structure disposed on the second surface of the semiconductor substrate; and a through via that passes through the semiconductor substrate, the first etch stop film, and the second etch stop film to connect the contact electrode and the lower wire structure, wherein the through via includes a first portion contacting the contact electrode and a second portion contacting the first portion and disposed between the first portion and the lower wire structure.

### CROSS-REFERENCE TO RELATED APPLICATION

This application claims priority to and the benefit of Korean Patent Application No. 10-2023-0022047 filed in the Korean Intellectual Property Office on Feb. 20, 2023, the entire contents of which are incorporated herein by reference.

### BACKGROUND

The present disclosure relates to a semiconductor device and a manufacturing method thereof.

Various semiconductor devices may be manufactured by using a semiconductor material, and for example, a memory device, a system large scale integration (LSI), and the like may be manufactured. These semiconductor devices may be used in various electronic devices.

As the electronics industry continues to advance, there is a growing demand for specific characteristics of the semiconductor devices. For example, there is an increasing demand for high reliability, high speed, and/or multifunctionality of the semiconductor devices. In order to meet these demand characteristics, structures in a semiconductor device are becoming increasingly complex and integrated.

### SUMMARY

Embodiments are directed a semiconductor device with improved reliability and a manufacturing method thereof.

An embodiment may provide a semiconductor device including: a semiconductor substrate having first and second surfaces opposite each other; a channel pattern disposed on the first surface of the semiconductor substrate; source/drain patterns disposed on the first surface of the semiconductor substrate and disposed at both sides of the channel pattern; first and second etch stop films disposed on the first surface of the semiconductor substrate; a contact electrode electrically connected to the source/drain patterns; a lower wire structure disposed on the second surface of the semiconductor substrate; and a through via that passes through the semiconductor substrate, the first etch stop film, and the second etch stop film to connect the contact electrode and the lower wire structure, wherein the through via includes a first portion contacting the contact electrode and a second portion contacting the first portion and disposed between the first portion and the lower wire structure.

Another embodiment provides a semiconductor device including: a semiconductor substrate having first and second surfaces opposite each other; a channel pattern disposed on the first surface of the semiconductor substrate; source/drain patterns disposed on the first surface of the semiconductor substrate and disposed at both sides of the channel pattern; a lower wire structure disposed on the second surface of the semiconductor substrate; a through via that passes through the semiconductor substrate and electrically connects the lower wire structure and the source/drain patterns; and an alignment pattern exposed through the second surface of the semiconductor substrate and disposed at a perimeter of the through via.

Another embodiment provides a manufacturing method of a semiconductor device, including: forming a groove on a first surface of a first semiconductor substrate having the first surface and a second surface opposite each other; forming an alignment pattern disposed on an inner side surface of the groove and a sacrificial layer filling the inside of the alignment pattern; attaching a second semiconductor substrate to the first surface of the first semiconductor substrate; forming a channel pattern, source/drain patterns, a gate structure, and an upper wire structure on the second semiconductor substrate; removing a portion of the second surface of the first semiconductor substrate to expose the alignment pattern and the sacrificial layer; removing the sacrificial layer to form a first hole; forming a second hole by etching the second semiconductor substrate exposed through the first hole; and forming at least a portion of a through via filling the second hole.

According to embodiments, reliability of electrical connection of through-vias may be secured. Accordingly, reliability of a semiconductor device may be improved.

### BRIEF DESCRIPTION OF THE DRAWINGS

FIG. 1 illustrates a top plan view of a semiconductor device according to an embodiment.

FIG. 2A illustrates a cross-sectional view taken along line Y1-Y1′ of FIG. 1.

FIG. 2B illustrates a cross-sectional view taken along line Y2-Y2′.

FIG. 2C illustrates a cross-sectional view taken along line X1-X1′.

FIG. 3 illustrates an enlarged view of a portion ‘R1’ of FIG. 2C.

FIG. 4A to FIG. 4K are cross-sectional views sequentially illustrating a manufacturing method of a semiconductor device according to an embodiment, and are cross-sectional views taken along line Y1-Y1′ of FIG. 1.

FIG. 5 and FIG. 6 illustrate cross-sectional views of a semiconductor device according to another embodiment, and illustrate cross-sectional views taken along line Y1-Y1′ of FIG. 1.

FIG. 7 illustrates a cross-sectional view of a semiconductor device according to an embodiment, and illustrates a cross-sectional view taken along line Y1-Y1′ of FIG. 1.

FIG. 8A to FIG. 8K are cross-sectional views sequentially illustrating a method of manufacturing the semiconductor device according to the embodiment of FIG. 7.

FIG. 9 illustrates a cross-sectional view of a semiconductor device according to another embodiment.

FIG. 10 illustrates a cross-sectional view of a semiconductor device according to an embodiment, and illustrates a cross-sectional view taken along line Y1-Y1′ of FIG. 1.

FIG. 11A and FIG. 11B are cross-sectional views sequentially illustrating a method of manufacturing the semiconductor device according to the embodiment of FIG. 10.

FIG. 12 illustrates a cross-sectional view of a semiconductor device according to another embodiment.

FIG. 13 illustrates a cross-sectional view of a semiconductor device according to an embodiment, and illustrates a cross-sectional view taken along line Y1-Y1′ of FIG. 1.

FIG. 14A to FIG. 14F are cross-sectional views sequentially illustrating a method of manufacturing the semiconductor device according to the embodiment of FIG. 13.

### DETAILED DESCRIPTION

The present disclosure will be described more fully hereinafter with reference to the accompanying drawings, in which embodiments are shown. As those skilled in the art would realize, the described embodiments may be modified in various different ways, all without departing from the spirit or scope of the present disclosure.

In order to clearly describe the present disclosure, parts or portions that are irrelevant to the description are omitted, and identical or similar constituent elements throughout the specification are denoted by the same reference numerals.

Further, in the drawings, the size and thickness of each element are arbitrarily illustrated for ease of description, and the present disclosure is not necessarily limited to those illustrated in the drawings. In the drawings, the thicknesses of layers, films, panels, regions, areas, etc., are exaggerated for clarity. In the drawings, for ease of description, the thicknesses of some layers and areas are exaggerated.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

In addition, unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

In the drawing of a semiconductor device according to an embodiment, illustratively, a three-dimensional field effect transistor including a nano wire or a nano sheet, MBCFET™ (multi-bridge channel field effect transistor) is shown, but is not limited thereto. In some embodiments, a semiconductor device may include a fin-type transistor (FinFET), a tunneling transistor (tunneling FET), or a three-dimensional (3D) transistor including a channel area of a fin-type pattern shape.

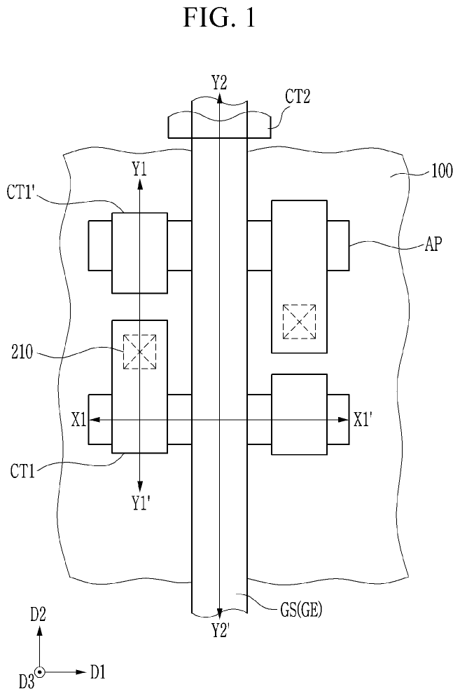

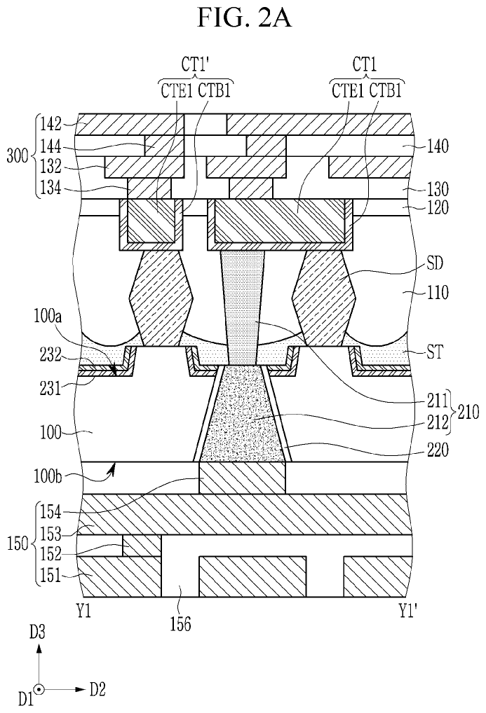

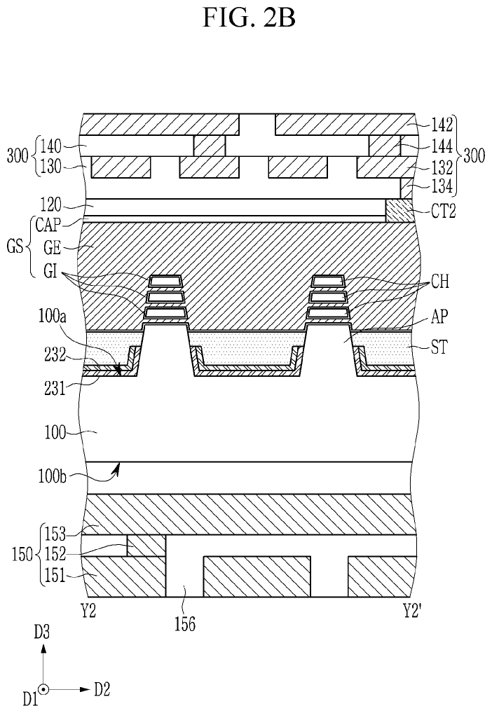

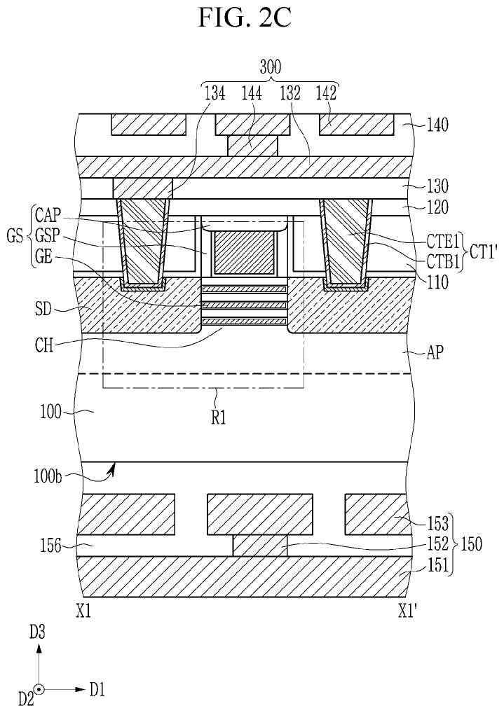

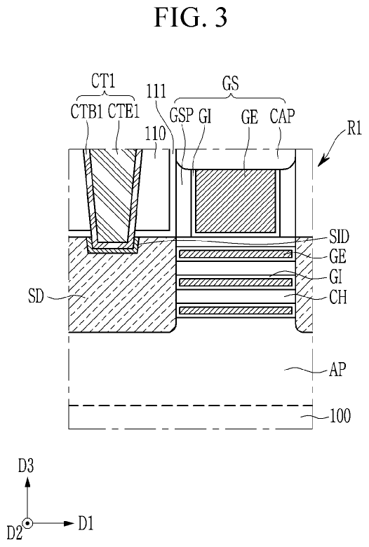

A semiconductor device according to an embodiment will be described with reference to FIG. 1, FIG. 2A, FIG. 2B, FIG. 2C, and FIG. 3.

FIG. 1 illustrates a top plan view of a semiconductor device according to an embodiment. FIG. 2A illustrates a cross-sectional view taken along line Y1-Y1′ of FIG. 1. FIG. 2B illustrates a cross-sectional view taken along line Y2-Y2′. FIG. 2C illustrates a cross-sectional view taken along line X1-X1′. FIG. 3 illustrates an enlarged view of a portion ‘R1’ of FIG. 2C.

Referring to FIG. 1 and FIG. 2A to FIG. 2C, a semiconductor device according to an embodiment may include a semiconductor substrate 100, active patterns AP disposed on the semiconductor substrate 100, first and second etch stop films 231 and 232 and a device separation film ST disposed between the active patterns AP, channel patterns CH disposed on the active patterns AP, a gate structure GS surrounding the channel patterns CH, source/drain patterns SD disposed at both sides of the channel patterns CH, first and second interlayer insulating layers 110 and 120 disposed on the source/drain patterns SD, an upper wire structure 300 disposed on the second interlayer insulating layer 120, a lower wire structure 150 disposed below the semiconductor substrate 100, and a through via 210 penetrating the semiconductor substrate 100.

The semiconductor substrate 100 may include a semiconductor material. For example, the semiconductor substrate 100 may include a group IV semiconductor, a group III-V compound semiconductor, and a group II-VI compound semiconductor. For example, the semiconductor substrate 100 may include or may be formed of a semiconductor such as Si or Ge, or a compound semiconductor such as SiGe, SiC, GaAs, InAs, or InP. The semiconductor substrate 100 may have an upper surface parallel to a first direction D1 and a second direction D2.

The semiconductor substrate 100 may include a first surface 100a and a second surface 100b opposite each other. In embodiments described later, the first surface 100a may be referred to as a front side of the semiconductor substrate 100, and the second surface 100b may be referred to as a back side of the semiconductor substrate 100. In some embodiments, a logic circuit of a cell area may be implemented on the first surface 100a of the semiconductor substrate 100.

The active patterns AP may be disposed at an upper portion of the semiconductor substrate 100. The active patterns AP are portions of the semiconductor substrate 100, and may be vertically protruding portions. The active patterns AP may be PMOSFET areas or NMOSFET areas.

The active patterns AP may protrude from the first surface 100a of the semiconductor substrate 100 along a third direction D3. The active patterns AP may be spaced apart from each other along the second direction D2. In this case, a first trench TR1 may be defined between the active patterns AP adjacent to each other. The active patterns AP may include or may be formed of semiconductors such as Si and Ge, and may include a group IV semiconductor, a group III-V compound semiconductor, or a group II-VI compound semiconductor.

The first and second etch stop films 231 and 232 may be disposed on bottom and side surfaces of the trench between the active patterns AP formed on the first surface 100a of the semiconductor substrate 100. The first and second etch stop films 231 and 232 may cover the first surface 100a of the semiconductor substrate 100 and the side surfaces of the active patterns AP. The first and second etch stop films 231 and 232 may cover all of the side surfaces of the active patterns AP, or may cover some (e.g., a portion) thereof. For example, the first and second etch stop films 231 and 232 may cover a lower portion of the side surface of the active patterns AP, and not cover an upper portion thereof. The first etch stop film 231 may include or may be formed of a silicon oxide (SiO₂), and the second etch stop film 232 may include or may be formed of at least one of a silicon nitride (SiN), a silicon oxynitride (SiON), a silicon carbonate nitride (SiCN), a silicon boron nitride (SiBN), a silicon carbon oxide (SiOC), and a combination thereof. The materials forming the first etch stop film 231 and the second etch stop film 232 are not limited thereto, and may include combinations of various materials with different etch selection ratios.

The device separation film ST may be disposed to cover the second etch stop film 232. The device separation film ST may fill the trenches between the active patterns AP. The device separation film ST may be formed to cover the side surfaces of the active patterns AP. The device separation film ST according to the embodiment is illustrated as entirely covering the side surfaces of the active patterns AP, but is not limited thereto, and the device separation film ST may cover some of the side surfaces of the active patterns AP. In this case, some of the active patterns AP may protrude further than the upper surface of the device separation film ST in the third direction D3. The device separation film ST may include or may be formed of, for example, a silicon oxide (SiO₂), a silicon nitride (SiN), a silicon oxynitride (SiON), or a combination thereof.

The channel patterns CH may be disposed on a plurality of active patterns AP. The channel patterns CH may be spaced apart from the active patterns AP in the third direction D3. Although it is illustrated that three channel patterns CH are disposed in the third direction D3, the present disclosure is not limited thereto. For example, four or more or two or fewer channel patterns CH may be disposed to be spaced apart from each other along the third direction DR3.

The channel patterns CH may include the same material as the active patterns AP. For example, the channel patterns CH may include or may be formed of semiconductors such as Si and Ge, and may include a group IV semiconductor, a group III-V compound semiconductor, and a group II-VI compound semiconductor. However, they are not limited thereto, and the channel patterns CH may include a material different from that of the active patterns AP.

The gate structure GS may be disposed on the first surface 100a of the semiconductor substrate 100. The gate structure GS may cross a plurality of the active patterns AP. The gate structure GS may extend in the second direction D2. The gate structures GS may be spaced apart from each other in the first direction D1. The gate structure GS may be disposed at both sides of the source/drain patterns SD.

Referring further to FIG. 3, each gate structure GS may include a gate electrode GE, a gate insulating pattern GI between the gate electrode GE and the channel patterns CH, a gate spacer GSP on side surfaces of the gate electrode GE, and a gate capping pattern CAP on an upper surface of the gate electrode GE.

The gate electrode GE may be disposed on the first surface 100a of the semiconductor substrate 100. The gate electrode GE may extend in the second direction D2. Respective gate electrodes GE may be spaced apart from each other in the first direction D1. The gate electrode GE may cross the active patterns AP. The gate electrode GE may surround respective channel patterns CH.

At least a portion of the gate electrode GE may be disposed on a stacked structure of the channel patterns CH. Another portion of the gate electrode GE may be formed to cover both side surfaces of the stacked structure of the channel patterns CH. Four surfaces of the channel patterns CH may be surrounded by a gate electrode GE.

The gate electrode GE may include or may be formed of at least one of a metal, a metal alloy, a conductive metal nitride, a doped semiconductor material, a conductive metal oxide, and a conductive metal nitride. The gate electrode GE may include or may be formed of, for example, at least one of a titanium nitride (TiN), a tantalum carbide (TaC), a tantalum nitride (TaN), a titanium silicon nitride (TiSiN), a tantalum silicon nitride (TaSiN), a tantalum titanium nitride (TaTiN), a titanium aluminum nitride (TiAlN), a tantalum aluminum nitride (TaAlN), a tungsten nitride (WN), ruthenium (Ru), a titanium aluminum (TiAl), a titanium aluminum carbonitride (TiAlC—N), a titanium aluminum carbide (TiAlC), a titanium carbide (TiC), a tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), a niobium nitride (NbN), a niobium carbide (NbC), molybdenum (Mo), a molybdenum nitride (MoN), a molybdenum carbide (MoC), a tungsten carbide (WC), rhodium (Rh), palladium (Pd), iridium (Ir), osmium (Os), silver (Ag), gold (Au), zinc (Zn), vanadium (V), and a combination thereof, but is not limited thereto. The conductive metal oxide and the conductive metal oxynitride may include oxidized forms of the above-mentioned materials, but are not limited thereto.

Referring to FIG. 3, the gate insulating pattern GI may surround the gate electrode GE. The gate insulating pattern GI may be disposed between the gate electrode GE and the channel patterns CH. The gate insulating pattern GI may extend between the gate electrode GE and the gate spacer GSP. An uppermost surface of the gate insulating pattern GI may be disposed at substantially the same level (e.g., in the third direction D3) as an upper surface of the gate electrode GE. The gate insulating pattern GI may be interposed between the upper surface of the channel patterns CH and the gate electrode GE.

The gate insulating pattern GI may include or may be formed of at least one of a silicon oxide (SiO₂), a silicon nitride (SiN), a silicon oxynitride (SiON), and a high dielectric film. The high dielectric film may include or may be formed of a material having a higher dielectric constant than that of a silicon oxide (SiO₂) such as a hafnium oxide (HfO), an aluminum oxide (AlO), or a tantalum oxide (TaO).

The gate spacer GSP may be disposed next to a sidewall of the gate electrode GE. The gate spacer GSP may not be disposed next to the sidewall of the gate electrode GE disposed between the active patterns AP and the channel patterns CH. The gate spacer GSP may not be disposed next to the sidewall of the gate electrode GE between the channel patterns CH adjacent to each other in the third direction D3.

The gate capping pattern CAP may be disposed on the gate electrode GE and the gate spacer GSP. An upper surface of the gate capping pattern CAP may be on the same plane as an upper surface of the first interlayer insulating layer 110. Unlike as shown, the gate capping pattern CAP may be disposed between the gate spacers GSP. That is, the gate spacer GSP may cover the side surface of the gate capping pattern CAP. Each of the gate spacer GSP and the gate capping pattern CAP may include or may be formed of at least one of a silicon oxide (SiO₂), a silicon nitride (SiN), and a silicon oxynitride (SiON).

The source/drain patterns SD may be formed to cover both side surfaces of the stacked structure of the gate electrode GE and the channel patterns CH. In this case, the source/drain patterns SD may be disposed at both sides of the channel patterns CH along the first direction D1.

The source/drain patterns SD may be epitaxial patterns formed by a selective epitaxial growth process using respective active patterns AP as a seed. The source/drain patterns SD may include or may be formed of, for example, at least one of silicon, a silicon germanium, and a silicon carbide. The channel patterns CH may be some of respective active patterns AP extending between the source/drain patterns SD. The source/drain patterns SD may serve as a source/drain of a transistor using the channel patterns CH as a channel area.

A third etch stop film 111 may be disposed on the side surface of the gate spacer GSP and on the upper surface of the source/drain patterns SD. The third etch stop film 111 may include or may be formed of, for example, at least one of a silicon nitride (SiN), a silicon oxynitride (SiON), a silicon carbonate nitride (SiCN), a silicon boronitride (SiBN), a silicon carbon oxide (SiOC), and a combination thereof.

The first interlayer insulating layer 110 may be disposed on the third etch stop film 111. The first interlayer insulating layer 110 may cover the source/drain patterns SD. The first interlayer insulating layer 110 may cover an upper surface of the device separation film ST.

The second interlayer insulating film 120 may be disposed on the first interlayer insulating layer 110. The second interlayer insulating layer 120 may cover an upper surface of the gate capping pattern CAP. The first and second interlayer insulating layers 110 and 120 may include or may be formed of, for example, at least one of a silicon oxide (SiO₂), a silicon nitride (SiN), a silicon oxynitride (SiON), and a low dielectric constant material. The low dielectric constant material may include or may be formed of, for example, Fluorinated TetraEthyl OrthoSilicate (FTEOS), Hydrogen SilsesQuioxane (HSQ), Bis-benzoCycloButene (BCB), TetraMethyl OrthoSilicate (TMOS), or a combination thereof, but is not limited thereto.

The second interlayer insulating layer 120 may cover a side surface of a first contact electrode CT1. In addition, an upper surface of the second interlayer insulating layer 120 may be disposed at substantially the same level (e.g., in the third direction D3) as an upper surface of the first contact electrode CT1. In FIG. 2A, the second interlayer insulating layer 120 and the first interlayer insulating layer 110 are shown as different layers, but the second interlayer insulating layer 120 may be integrally formed with the first interlayer insulating layer 110 without a boundary surface therebetween.

The first contact electrodes CT1 and CT1′ may pass through the first interlayer insulating layer 110 and the second interlayer insulating layer 120 to be connected to source/drain patterns SD. The first contact electrodes CT1 and CT1′ may be disposed at both sides of each gate structure GS. The first contact electrodes CT1 and CT1′ may have a bar shape extending in the second direction D2.

Each of the first contact electrodes CT1 and CT1′ may be connected to a plurality of the source/drain patterns SD spaced apart from each other in a second direction D2. For example, as shown in FIG. 3, the bottom surfaces of the first contact electrodes CT1 and CT1′ may be disposed at a level (e.g., in the third direction D3) similar to the lower surface of the uppermost channel pattern among the channel patterns CH. However, the bottom surfaces of the first contact electrodes CT1 and CT1′ may be higher or lower than the lower surface of the uppermost channel pattern among the channel patterns CH. Some CT1 of the first contact electrodes CT1 and CT1′ may be connected to the through via 210.

The first contact electrodes CT1 and CT1′ according to the embodiment may include a first conductive pattern CTE1 and a first barrier pattern CTB1 surrounding it.

The first conductive pattern CTE1 may include or may be formed of, for example, at least one of a metal, a metal alloy, a conductive metal nitride, a conductive metal carbide, a conductive metal oxide, a conductive metal carbonitride, and a two-dimensional (2D) material.

The first barrier pattern CTB1 may cover the sidewalls and bottom surface of the first conductive patterns CT1 and CT1′. The first barrier pattern CTB1 may include or may be formed of a metal, a metal alloy, and a conductive metal nitride. The metal may include or may be formed of at least one of titanium (Ti), tantalum (Ta), tungsten (W), nickel (Ni), cobalt (Co), and platinum (Pt). The conductive metal nitride may include or may be formed of at least one of a titanium nitride (TiN), a tantalum nitride (TaN), a tungsten nitride (WN), a nickel nitride (NiN), a cobalt nitride (CON), and a platinum nitride (PtN).

Although the first contact electrodes CT1 and CT1′ according to the embodiment are illustrated as being a double layered film including the first conductive pattern CTE1 and the first barrier pattern CTB1, this is for illustrative purposes only and is not intended to be limiting.

A metal silicide film SID may be further disposed between the source/drain patterns SD and the first contact electrodes CT1 and CT1′. The metal silicide film SID may include or may be formed of a metal silicide.

Referring back to FIG. 2A to FIG. 2C, a second contact electrode CT2 may be disposed within the second interlayer insulating layer 120. The second contact electrode CT2 may pass through the second interlayer insulating layer 120 and the gate capping pattern CAP to be connected to the gate electrode GE. The upper surfaces of the first contact electrodes CT1 and CT1′ and the second contact electrode CT2 may be disposed at substantially the same level (e.g., in the third direction D3) as the upper surface of the second interlayer insulating layer 120. For example, the upper surfaces of the first contact electrodes CT1 and CT1′ and the second contact electrode CT2 may be substantially at the same height (e.g., level) as the upper surface of the second interlayer insulating layer 120 with respect to the second surface 100b of the semiconductor substrate 100.

The first contact electrodes CT1 and CT1′ and the second contact electrode CT2 may include the same conductive material. The first contact electrodes CT1 and CT1′ and the second contact electrode CT2 may include a metallic material. For example, the first contact electrodes CT1 and CT1′ and the second contact electrode CT2 may include or may be formed of, for example, at least one of a metal, a metal alloy, a conductive metal nitride, a conductive metal carbide, a conductive metal oxide, a conductive metal carbonitride, and a two-dimensional (2D) material.

The upper wire structure 300 may be disposed on the second interlayer insulating layer 120. The upper wire structure 300 may include first upper wires 132, first upper vias 134, second upper wires 142, second upper vias 144, a third interlayer insulating layer 130, and a fourth interlayer insulating layer 140.

Specifically, the third interlayer insulating film 130 may be disposed on the second interlayer insulating layer 120. The third interlayer insulating layer 130 may cover the upper surfaces of the first contact electrodes CT1 and CT1′ and the second contact electrode CT2. The third interlayer insulating layer 130 may also contact the upper surfaces of the first contact electrodes CT1 and CT1′ and the second contact electrode CT2.

The first upper wires 132 and the first upper vias 134 may be disposed within the third interlayer insulating layer 130. The first upper wires 132 may pass through an upper portion of the third interlayer insulating layer 130. Upper surfaces of the first upper wires 132 may be disposed at a level (in the third direction D3) substantially equal to an upper surface of the third interlayer insulating layer 130. For example, the upper surfaces of the first upper wires 132 may be at a substantially equal height (e.g., level) to the upper surface of the third interlayer insulating layer 130 with respect to the second surface 100b of the semiconductor substrate 100.

The first upper vias 134 may be disposed between the first contact electrodes CT1 and CT1′ and the first upper wires 132 and between the second contact electrode CT2 and the first upper wires 132. The first upper vias 134 may pass through a lower portion of the third interlayer insulating layer 130. Each of the first contact electrodes CT1 and CT1′ and the second contact electrode CT2 may be electrically connected to the first upper wires 132 through the first upper vias 134.

The fourth interlayer insulating film 140 may be disposed on the third interlayer insulating layer 130. The fourth interlayer insulating layer 140 may cover the upper surfaces of the first upper wires 132.

The second upper wires 142 and the second upper vias 144 may be disposed within the fourth interlayer insulating layer 140. The second upper wires 142 may pass through an upper portion of the fourth interlayer insulating layer 140. Upper surfaces of the second upper wires 142 may be disposed at a level (in the third direction D3) substantially equal to an upper surface of the fourth interlayer insulating layer 140. That is, the upper surfaces of the second upper wires 142 may be at a substantially equal height (e.g., level) to the upper surface of the fourth interlayer insulating layer 140 with respect to the second surface 100b of the semiconductor substrate 100.

The second upper vias 144 may be disposed between the first upper wires 132 and the second upper wires 142. The second upper vias 144 may pass through a lower portion of the fourth interlayer insulating layer 140. The first upper wires 132 may be electrically connected to the second upper wires 142 through the second upper vias 144, respectively.

The third and fourth interlayer insulating layers 130 and 140 may include or may be formed of, for example, at least one of a silicon oxide (SiO₂), a silicon nitride (SiN), a silicon oxynitride (SiON), and a low dielectric film. The first and second upper wires 132 and 142 and the first and second upper vias 134 and 144 may include or may be formed of at least one of a metal and a conductive metal nitride.

The lower wire structure 150 may be disposed on the second surface 100b of the semiconductor substrate 100. The lower wire structure 150 may be, for example, a power delivery network that supplies a power voltage to the source/drain patterns SD. The lower wire structure 150 may include lower wires 151 and 153, lower vias 152 and 154, and a lower insulating layer 156.

The lower wires 151 and 153 and the lower vias 152 and 154 may be disposed on the second surface 100b of the semiconductor substrate 100. The lower wires 151 and 153 and the lower vias 152 and 154 may include or may be formed of a metal (for example, copper). The lower wires 151 and 153 and the lower vias 152 and 154 may be electrically connected to a second portion 212 of through via 210. A detailed description thereof will be described later.

The lower insulating layer 156 may be disposed on the second surface 100b of the semiconductor substrate 100. The lower insulating layer 156 may be disposed between the second surface 100b of the semiconductor substrate 100, the lower wires 151 and 153, and the lower vias 152 and 154 to insulate them. That is, the lower insulating layer 156 may cover the second surface 100b of the semiconductor substrate 100 and the lower wires 153, and the lower wires 151 and 153 and the lower vias 152 and 154 may be disposed within the lower insulating layer 156. The lower insulating layer 156 may include or may be formed of, for example, at least one of a silicon oxide (SiO₂), a silicon nitride (SiN), a silicon oxynitride (SiON), and a low dielectric film.

The through via 210 may be disposed within the semiconductor substrate 100. The through via 210 may pass through the first interlayer insulating layer 110, the device separation film ST, and the semiconductor substrate 100 to connect the first contact electrode CT1 and the lower wire structure 150. The through via 210 may be electrically connected to the first contact electrode CT1 and the lower wire structure 150, respectively. The through via 210 may extend in the first direction D1.

The through via 210 may include a first portion 211 and a second portion 212. The first portion 211 may be disposed between the first contact electrode CT1 and the second portion 212, and the second portion 212 may be disposed between the first portion 211 and the lower wire structure 150. The first portion 211 may pass through the first interlayer insulating layer 110 and the device separation film ST, and the second portion 212 may pass through the first and second etch stop films 231 and 232 and the semiconductor substrate 100. A width of the first portion 211 may decrease as it goes downward (as it approaches the second portion 212), and a width of the second portion 212 may increase as it goes downward (as it approaches the second surface 100b). Although not shown, the second portion 212 may be disposed so as to extend long in the first direction D1 and cross the gate structure GS in an insulated state. That is, the second portion 212 may extend longer in the first direction D1 than the first portion 211. A side insulating film 220 may disposed between the second portion 212 and the semiconductor substrate 100 to insulate them. The side insulating film 220 may also be disposed between the second portion 212 and the first and second etch stop films 231 and 232. The side insulating film 220 may contact the second portion 212. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The first portion 211 of the through via 210 may include the same material as the first contact electrode CT1. The first portion 211 of the through via 210 may include or may be formed of, for example, at least one of a metal, a metal alloy, a conductive metal nitride, a conductive metal carbide, a conductive metal oxide, and a conductive metal carbonitride. However, it is not limited thereto, and the first portion 211 of the through via 210 may include or may be formed of a different material from that of the first contact electrode CT1.

The second portion 212 of the through via 210 may include the same material as the first portion 211. The second portion 212 of the through via 210 may include or may be formed of, for example, at least one of a metal, a metal alloy, a conductive metal nitride, a conductive metal carbide, a conductive metal oxide, and a conductive metal carbonitride. However, it is not limited thereto, and the second portion 212 of the through via 210 may include or may be formed of a different material from that of the first portion 211 of the through via 210.

In summary, the through via 210 of the semiconductor device according to the embodiment may be electrically connected to the lower wire structure 150. In addition, the through via 210 may be electrically connected to the first contact electrode CT1. That is, the first contact electrode CT1 may be electrically connected to the lower wire structure 150 through the through via 210. The lower wire structure 150 may apply a power voltage or a ground voltage to the first contact electrode CT1 through the through via 210.

In this case, since the lower wire structure 150 is disposed on the rear surface of the semiconductor substrate 100, the lower wire structure 150 may not occupy a separate area within the semiconductor device. Accordingly, a gap for insulation between the wire layers of the upper wire structure 300 disposed on the front surface of the semiconductor substrate 100 may be easily secured.

The through via 210 may be formed by depositing a conductive material in the through hole penetrating the first interlayer insulating layer 110 and the device separation film ST and the through hole penetrating the semiconductor substrate 100. The first and second etch stop films 231 and 232 may function as an etch stop film when forming through holes for forming the through via 210, and by applying these, it is possible to more reliably form the through hole penetrating the first interlayer insulating layer 110 and the device separation film ST and the through holes penetrating the semiconductor substrate 100. Through this, reliability of the electrical connection between the first portion 211 and the second portion 212 of the through via 210 may be secured. Therefore, a semiconductor device with improved reliability may be provided.

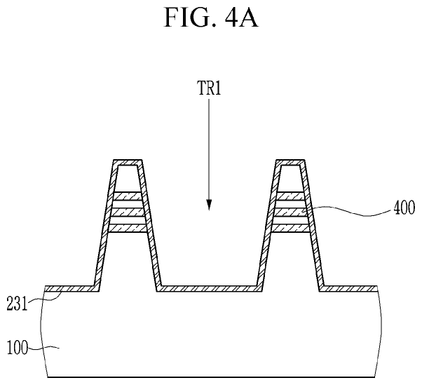

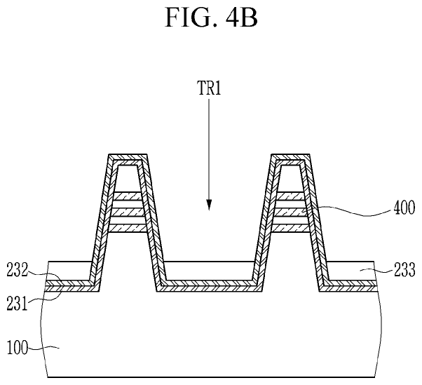

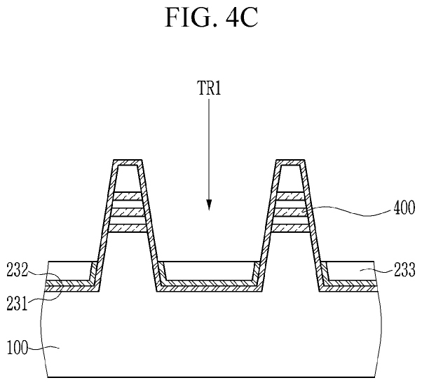

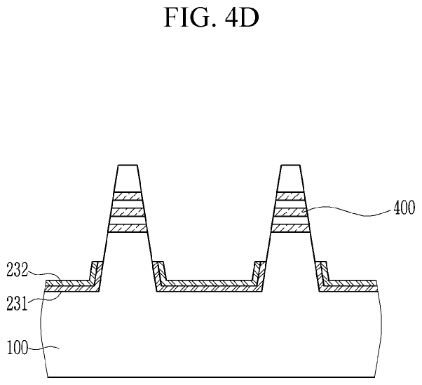

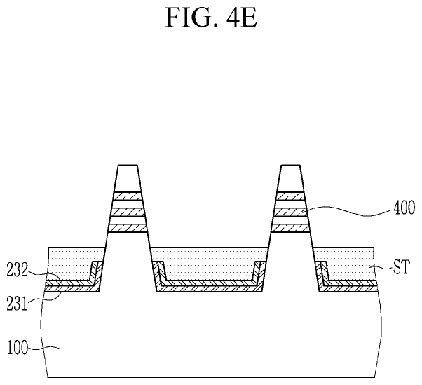

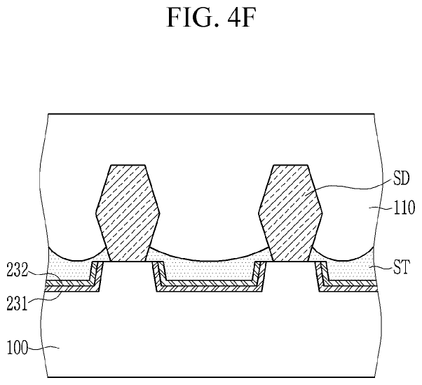

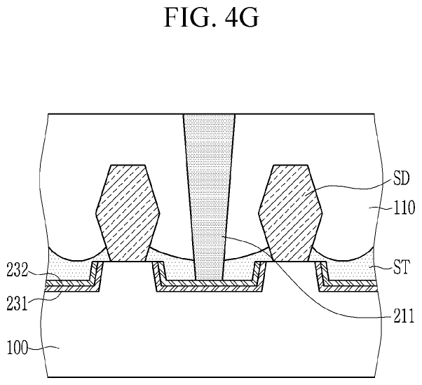

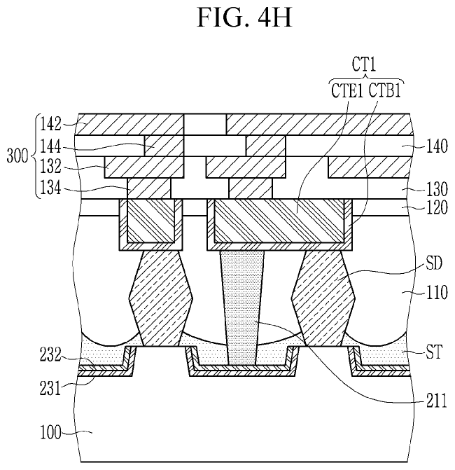

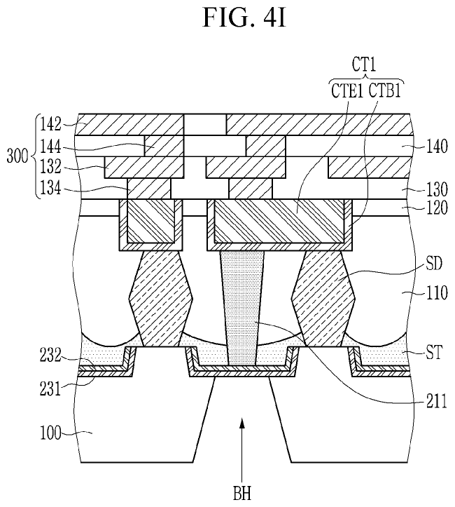

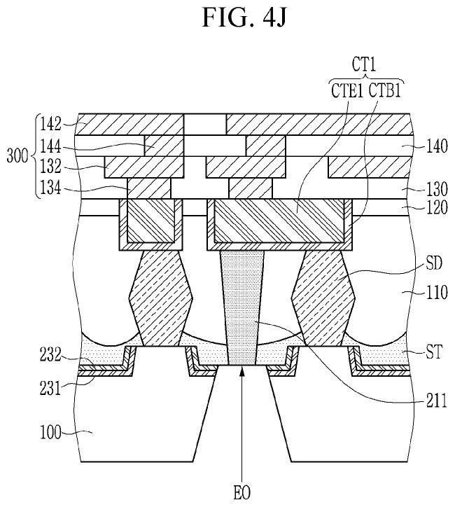

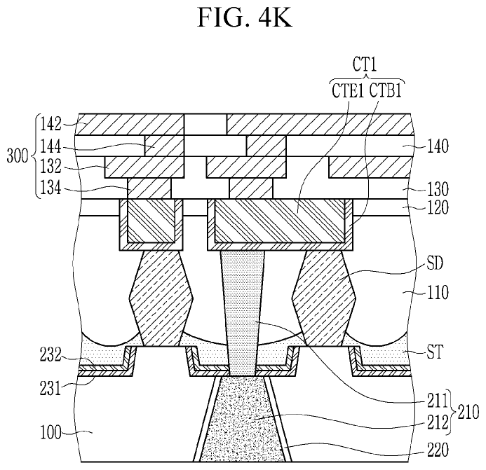

Hereinafter, a manufacturing method of a semiconductor device according to an embodiment, will be described with reference to FIG. 4A to FIG. 4K.

FIG. 4A to FIG. 4K are cross-sectional views sequentially illustrating a manufacturing method of a semiconductor device according to an embodiment, and are cross-sectional views taken along line Y1-Y1′ of FIG. 1.

Referring to FIG. 4A, a stacked structure may be formed by repeatedly stacking a sacrificial layer 400 and the semiconductor layer on the semiconductor substrate 100, and preliminary active patterns may be formed by photo-etching the stacked structure and the semiconductor substrate 100. The preliminary active patterns may be separated by the trench TR1. The first etch stop film 231 may be formed on the preliminary active patterns.

Referring to FIG. 4B, the second etch stop film 232 may be formed on the first etch stop film 231, and a mask layer 233 partially filling the inside of the trench TR1 may be formed on the second etch stop film 232. The mask layer 233 may be made of a silicon oxide or the like, and may be formed by a method such as film deposit and etch-back or photolithography.

Referring to FIG. 4C, the second etch stop film 232 may be etched by using the mask layer 233 as an etch mask.

Referring to FIG. 4D, the first etch stop film 231 may be etched by using the mask layer 233 and the second etch stop film 232 as an etch mask. Then, the remaining mask layer 233 may be removed.

Referring to FIG. 4E, the device separation film ST partially filling the inside of the trench TR1 may be formed. The device separation film ST may completely cover the first and second etch stop films 231 and 232, and may not cover the side surface of the lowermost sacrificial layer 400.

Referring to FIG. 4F, FIG. 2A to FIG. 2C, and FIG. 3, the active patterns AP and the channel patterns CH thereon, the gate structure GS, and the source/drain patterns SD may be formed. Subsequently, the first interlayer insulating layer 110 may be formed to cover the device separation film ST and the source/drain patterns SD.

The source/drain patterns SD may be formed by using an epitaxial growth method. The source/drain patterns SD may include or may be formed of silicon germanium (SiGe). However, they are not limited thereto, and the material of the source/drain patterns SD may be variously changed.

The gate structure GS may be formed by removing the sacrificial layer 400 and forming the gate insulating pattern GI, the gate electrode GE, the gate capping pattern, and the like in a space in which the sacrificial layer 400 is removed. The gate electrode GE may be formed by using an atomic layer deposition (ALD) process, a chemical vapor deposition (CVD) process, or the like. Accordingly, the gate structure GS may cover the upper surface of the channel patterns CH, and may cover both side surfaces of the channel patterns CH. The source/drain patterns SD may be disposed at both sides of each gate structure GS.

Referring to FIG. 4G, the first portion 211 of the through via 210 passing through the first interlayer insulating layer 110 and the device separation film ST may be formed. A through hole exposing the second etch stop film 232 is formed by photo-etching the first interlayer insulating layer 110 and the device separation film ST, and the first portion 211 may be formed by filling the through hole with a conductive material including a metal or a metal alloy. In this case, by disposing the second etch stop film 232, etching for forming the through hole may be sufficiently performed, so that the through hole may be reliably formed. Therefore, the first portion 211 of the through via 210 may also be reliably formed.

Referring to FIG. 4H, the second interlayer insulating layer 120 may be formed on the first interlayer insulating layer 110, and the first contact electrodes CT1 and CT1′ may be formed within the first interlayer insulating layer 110 and the second interlayer insulating layer 120. Before forming the first contact electrodes CT1 and CT1′, the upper surface of the second interlayer insulating layer 120 may be planarized by using a chemical mechanical polishing (CMP) process or the like.

The first portion 211 of the through via 210 and the first contact electrode CT1 may be formed together in one process. In this case, the second interlayer insulating layer 120 is first formed, a groove for forming the first contact electrode CT1 and a through hole for forming the first portion 211 of the through via 210 are formed, and then a conductive layer forming the first contact electrode CT1 and the first portion 211 of the through via 210 may be formed.

Subsequently, the third interlayer insulating layer 130 may be formed on the second interlayer insulating layer 120, and the first upper wires 132 and the first upper vias 134 may be formed within the third interlayer insulating layer 130. The fourth interlayer insulating layer 140 may be formed on the third interlayer insulating layer 130, and the second upper wires 142 and the second upper vias 144 may be formed within the fourth interlayer insulating layer 140. Although not shown, additional interlayer insulating layers, additional upper wires, and additional upper vias may be formed on the fourth interlayer insulating layer 140.

Referring to FIG. 4I, a rear through hole BH exposing the first etch stop film 231 may be formed by photo-etching the semiconductor substrate 100. In this case, since the first etch stop film 231 is disposed, etching for forming the rear through hole BH may be sufficiently performed, so that the rear through hole BH may reliably be formed. This process may be performed in a state in which a carrier substrate (not shown) is attached on the fourth interlayer insulating layer 140 and the entire structure is turned over so that the rear surface of the semiconductor substrate 100 faces upward.

Referring to FIG. 4J, an etch stop film hole EO that exposes the first portion 211 of the through via 210 and the device separation film ST by etching the first and second etch stop films 231 and 232 exposed through the rear through hole BH may be formed. There is etch selectivity between the first etch stop film 231 and the second etch stop film 232, and there is etch selectivity between the second etch stop film 232 and the device separation film ST, so that it is possible to reliably form the rear through hole BH and the etch stop film hole EO, and it is possible to prevent unwanted etching of the device separation film ST when the etch stop film hole EO is formed.

Referring to FIG. 4K, the side insulating film 220 covering the side surfaces of the rear through hole BH and the etch stop film hole EO may be formed, and the second portion 212 of the through via 210 filling the rear through hole BH and the etch stop film hole EO may be formed.

Referring to FIG. 2A, the lower wire structure 150 electrically connected to the second portion 212 of the through via 210 may be formed on the second surface 100b of the semiconductor substrate 100. The lower wire structure 150 may include the lower wires 151 and 153, the lower vias 152 and 154, and the lower insulating layer 156. The lower wires 151 and 153 and the lower vias 152 and 154 may include or may be formed of a metal (for example, copper).

Next, the semiconductor device of FIG. 1 to FIG. 3 may be manufactured by removing the carrier substrate and the adhesive film.

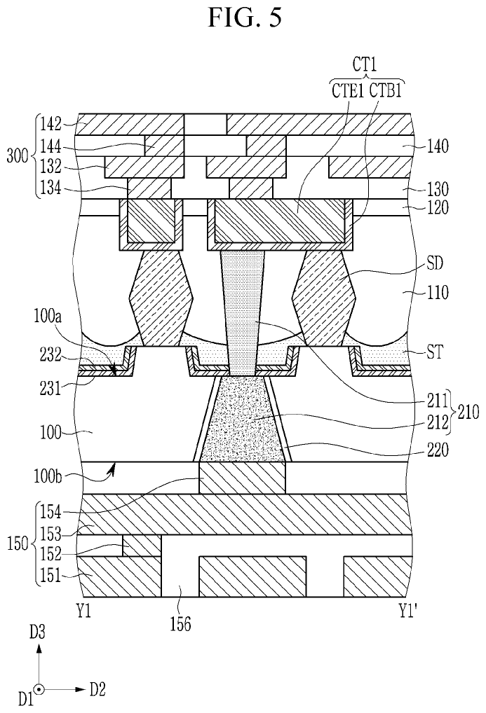

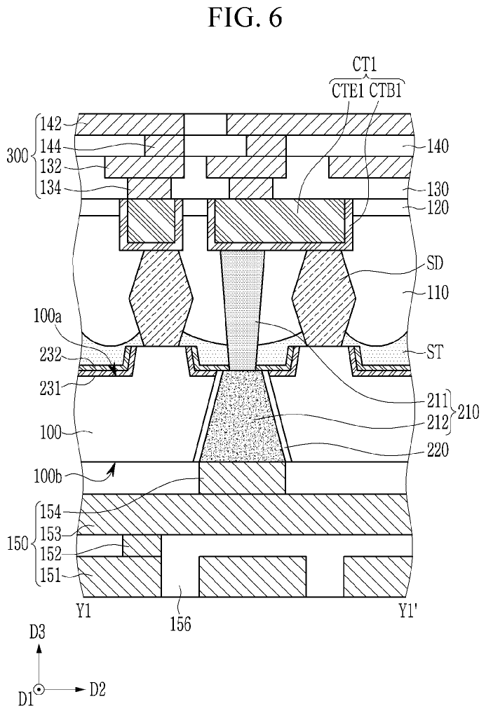

FIG. 5 and FIG. 6 illustrate cross-sectional views of a semiconductor device according to another embodiment, and illustrate cross-sectional views taken along line Y1-Y1′ of FIG. 1.

In the semiconductor device according to the embodiment of FIG. 5 and FIG. 6, the penetration of the through via 210 with respect to the first and second etch stop films 231 and 232 differ as compared to the embodiment of FIG. 2A. In FIG. 2A, the second portion 212 of the through via 210 passes through the first and second etch stop films 231 and 232 to contact the first portion 211 of the through via 210 and the surrounding device separation film ST, but in FIG. 5, the first portion 211 of the through via 210 passes through the first and second etch stop films 231 and 232 to contact the second portion 212 of the through via 210 that is in contact with the lower surface of the first etch stop film 231. In FIG. 6, the first portion 211 of the through via 210 passes through the second etch stop film 232 and the second portion 212 of the through via 210 passes through the first etch stop film 231 such that the first portion 211 and the second portion 212 contact each other near the boundary between the first etch stop film 231 and the second etch stop film 232.

In this way, when the first and second etch stop films 231 and 232 are applied, the timing of piercing the first and second etch stop films 231 and 232 may be adjusted as needed, so that the depth of contact between the first portion 211 and the second portion 212 of the through via 210 may be adjusted. As a result, contact failure due to thickness deviation of the semiconductor substrate 100 or the insulating films ST, 120, and 130 may be prevented. In addition, the flatness of the contact surfaces of the first portion 211 and the second portion 212 of the through via 210 is improved, so that uniform and stable contact may be ensured. In addition, the first and second etch stop films 231 and 232 together with the side insulating film 220 may function as an insulating film separating the semiconductor substrate 100 and the second portion 212 of the through via 210 to ensure insulation between the through via 210 and the semiconductor substrate 100.

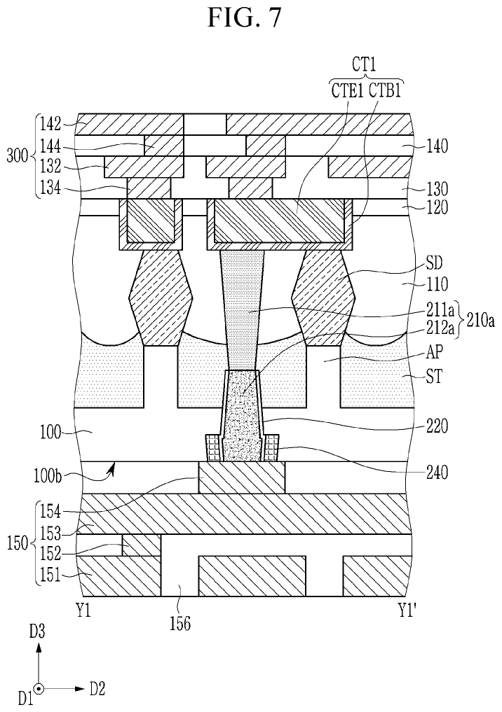

FIG. 7 illustrates a cross-sectional view of a semiconductor device according to an embodiment, and illustrates a cross-sectional view taken along line Y1-Y1′ of FIG. 1.

The embodiment shown in FIG. 7 has substantially the same portions as the embodiment shown in FIG. 1 and FIG. 2A to FIG. 2C, so a description thereof will be omitted and differences will be mainly described. In the embodiment of FIG. 7, the shape of the through via 210a is different from those of the previous embodiments, and the first and second etch stop films 231 and 232 are not applied. Hereinafter, it will be described in more detail.

Referring to FIG. 7, the through via 210a passing through the semiconductor substrate 100, the device separation film ST, and the first interlayer insulating layer 110 may be disposed. The through via 210a may include a first portion 211a partially penetrating the first interlayer insulating layer 110 and the device separation film ST and a second portion 212a penetrating the semiconductor substrate 100 and partially penetrating the device separation film ST. The first portion 211a and the second portion 212a may contact each other within the device separation film ST. The through via 210a may electrically connect the via 154 of the lower wire structure 150 and the first contact electrode CT1.

The side insulating film 220 may be disposed on the side surface of the second portion 212a of the through via 210a, and an alignment pattern 240 may be disposed at (e.g., along) the perimeter (e.g., circumference) of the second portion 212a near the rear surface 100b of the semiconductor substrate 100. The alignment pattern 240 may be disposed between the second portion 212a and the semiconductor substrate 100. For example, the alignment pattern 240 may be disposed between the side insulating film 220 and the semiconductor substrate 100, and may have a ring shape or a shape similar to a shape of the perimeter of the second portion 212a. The alignment pattern 240 may be used as a self-alignment mask when forming a through hole for forming the second portion 212a, or may be an insulator such as a silicon oxide. The side shape of the second portion 212a may be bent between a portion overlapping the alignment pattern 240 and a portion not overlapping the alignment pattern 240 in the second direction D2. For example, the slopes of the side surface of the second portion 212a may be different at the portion overlapping the alignment pattern 240 and at the portion not overlapping the alignment pattern 240. In other words, the cross section of the second portion 212a gradually widens as it goes downward (closer to the second surface 100b) in the portion not overlapping the alignment pattern 240, and the cross section of the second portion 212a may gradually narrow or remain substantially constant in the portion overlapping the alignment pattern 240.

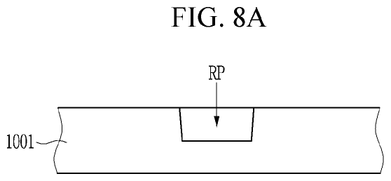

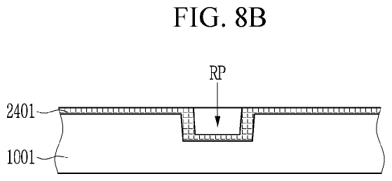

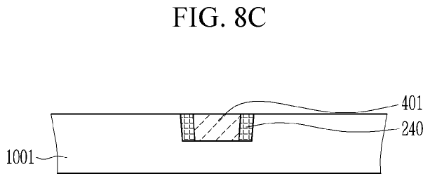

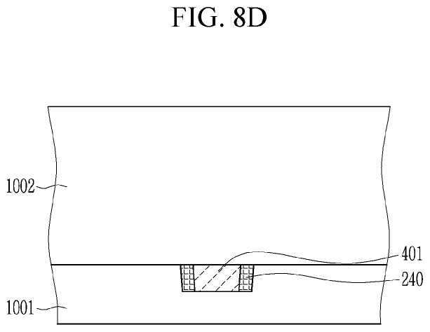

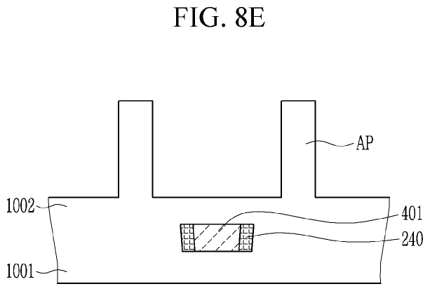

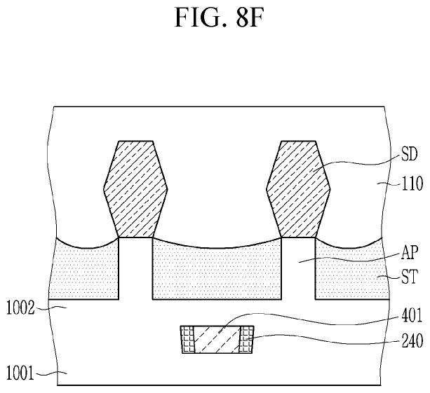

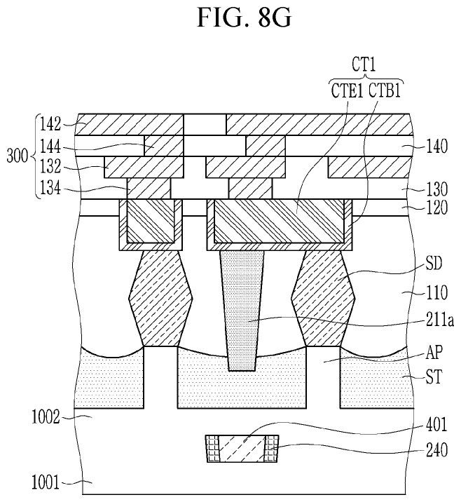

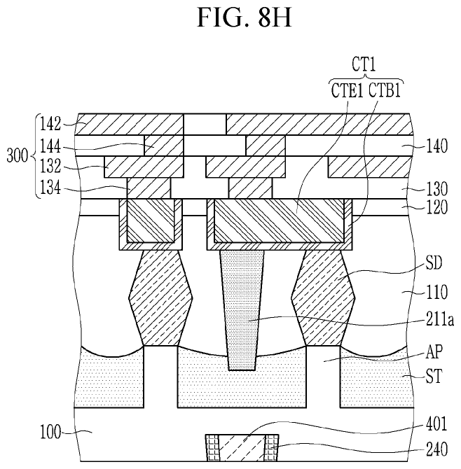

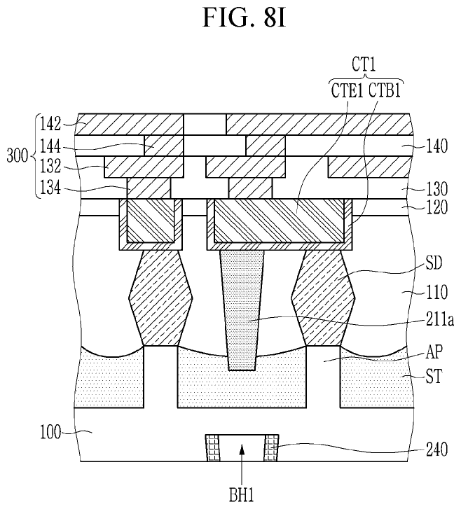

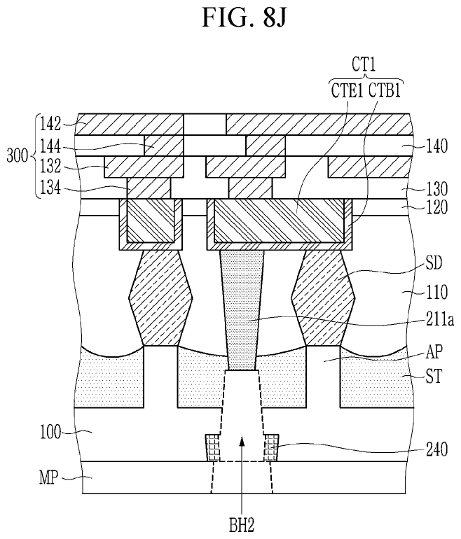

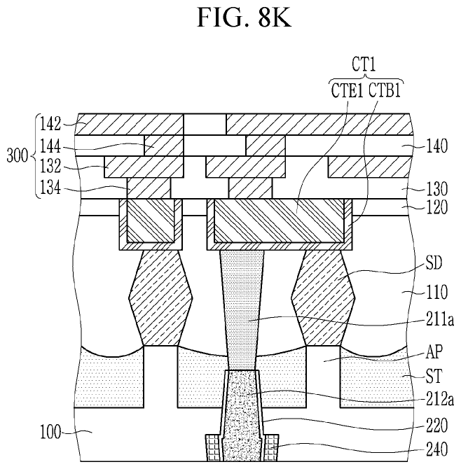

Hereinafter, a manufacturing method of a semiconductor device according to an embodiment will be described with reference to FIG. 8A to FIG. 8K.

FIG. 8A to FIG. 8K are cross-sectional views sequentially illustrating a method of manufacturing the semiconductor device according to the embodiment of FIG. 7.

Referring to FIG. 8A, a groove RP of a predetermined depth may be formed on one surface of a first semiconductor substrate 1001.

Referring to FIG. 8B, an insulating film 2401 for an alignment pattern may be deposited on one surface of the first semiconductor substrate 1001 and the side and bottom surfaces of the groove RP.

Referring to FIG. 8C, the alignment pattern 240 may be formed by anisotropically etching the insulating film 2401 for the alignment pattern. The insulating film 2401 for the alignment pattern disposed on one surface of the first semiconductor substrate 1001 and the bottom surface of the groove RP is removed, and a portion thereof covering the side surface of the groove RP remains, so that the alignment pattern 240 may be formed. Subsequently, a sacrificial layer 401 filling the inside of the alignment pattern 240 may be formed. For example, the sacrificial layer 401 may fill a remaining portion (e.g., a center portion) of the groove RP after the alignment pattern 240 is formed in the groove RP. The sacrificial layer 401 may be made of a material having etching selectivity with the alignment pattern 240 or the first semiconductor substrate 1001, and may include or may be formed of silicon germanium (SiGe) or the like. The sacrificial layer 401 may be formed through film formation and an etch-back or chemical mechanical polishing (CMP) process.

Referring to FIG. 8D, a second semiconductor substrate 1002 is attached to one surface of the first semiconductor substrate 1001 on which the alignment pattern 240 and the sacrificial layer 401 are formed. Referring to FIG. 8E, the active patterns AP may be formed by patterning a portion of the second semiconductor substrate 1002.

Referring to FIG. 8F and FIG. 7, the channel patterns, the gate structure, and the source/drain patterns SD may be formed on the active patterns AP. Subsequently, the first interlayer insulating layer 110 covering the device separation film ST and the source/drain patterns SD may be formed. The source/drain patterns SD may be formed by using an epitaxial growth method. The source/drain patterns SD may include or may be formed of silicon germanium (SiGe). However, they are not limited thereto, and the material of the source/drain patterns SD may be variously changed.

Referring to FIG. 8G, the first portion 211a of the through via 210a passing through the first interlayer insulating layer 110 and the device separation film ST may be formed, and the second interlayer insulating layer 120 may be formed on the first interlayer insulating layer 110. The first contact electrode CT1 may be formed in the first interlayer insulating layer 110 and the second interlayer insulating layer 120. Before forming the first contact electrode CT1, the upper surface of the second interlayer insulating layer 120 may be planarized by using a chemical mechanical polishing (CMP) process or the like. In some embodiments, the second interlayer insulating layer 120 may be omitted.

The first portion 211a of the through via 210a and the first contact electrode CT1 may be formed together in one process. In this case, the second interlayer insulating layer 120 is first formed, a groove for forming the first contact electrode CT1 and a through hole for forming the first portion 211a of the through via 210a are formed, and then a conductive layer forming the first contact electrode CT1 and the first portion 211a of the through via 210a may be formed.

When forming the through hole for forming the first portion 211a of the through via 210a, the alignment pattern 240 and the sacrificial layer 401 formed near the front surface of the first semiconductor substrate 1001 may serve as an alignment key to accurately dispose the first portion 211a of the through via 210a at a desired position.

Next, the upper wire structure 300 may be formed on the second interlayer insulating layer 120.

Referring to FIG. 8H, the lower portion of the first semiconductor substrate 1001 may be removed to expose the alignment pattern 240 and the sacrificial layer 401. This process may be performed through a chemical mechanical polishing (CMP) or etch-back process. This process may be performed in a state in which a carrier substrate (not shown) is attached on the upper wire structure 300 and the entire structure is turned over so that the rear surface of the first semiconductor substrate 1001 faces upward.

Referring to FIG. 8I, the sacrificial layer 401 may be removed to form a first rear hole BH1. This process may be performed by a photo etching process or an etching back using an etching method having etching selectivity for the sacrificial layer 401.

Referring to FIG. 8J, an etching mask pattern MP is formed on the rear surface of the semiconductor substrate 100, and the semiconductor substrate 100 and the device separation layer ST exposed through the first rear hole BH1 are etched, so that a second rear hole BH2 may be formed. A bottom surface of the first portion 211a of the through via may be exposed through the second rear hole BH2.

In some embodiments, after the etching mask pattern MP is formed, the sacrificial layer 401 is removed to form the first rear hole BH1, and the semiconductor substrate 100 and the second separation layer ST exposed through the first rear hole BH1 are etched, so that the rear hole BH2 may be formed.

Since the alignment pattern 240 is disposed, the misalignment tolerance of the etching mask pattern MP may be increased.

Referring to FIG. 8K, the side insulating film 220 may be formed on the side surface of the second rear hole BH2, and the second portion 212 of the through via filling the second rear hole BH2 may be formed. The side insulating film 220 may be formed through insulating film deposition and anisotropic etching.

Subsequently, the lower wire structure 150 may be formed on the rear surface of the semiconductor substrate 100.

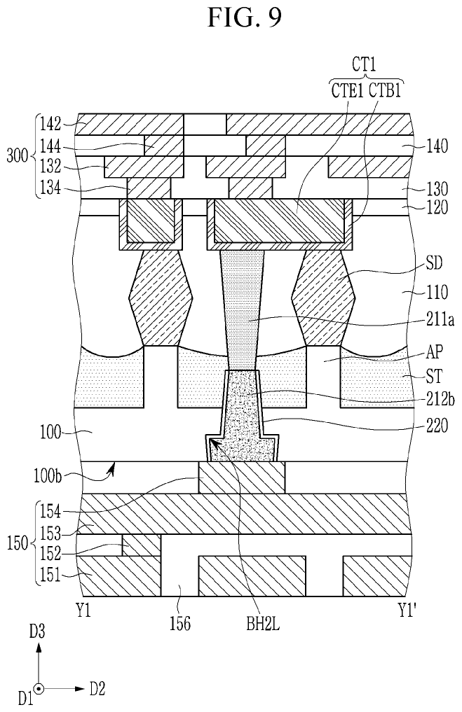

FIG. 9 illustrates a cross-sectional view of a semiconductor device according to another embodiment.

The embodiment of FIG. 9 is different from the embodiment of FIG. 7 in that the alignment pattern 240 is removed and a lower end portion BH2L of the second rear hole BH2 is extended, the side insulating film 220 is also formed on the side and bottom surfaces of the lower end BH2L of the second rear hole BH2, which is extended by removing the alignment pattern 240, and second portion 212b of the through via fills the portion in which the alignment pattern 240 is removed. Accordingly, in the second portion 212b of the through via, a step may be formed between the lower end portion and the remaining portion thereon, and the side slope of the lower end portion may be different from that of the remaining portion.

This structure may be implemented, after the step of FIG. 8J, by removing the alignment pattern 240 and forming the side insulating film 220 and the second portion 212b of the through via. The alignment pattern 240 may be removed before or after the etching mask pattern MP is removed, and the removing of the alignment pattern 240 may be performed through an etching method having etching selectivity with respect to the alignment pattern 240.

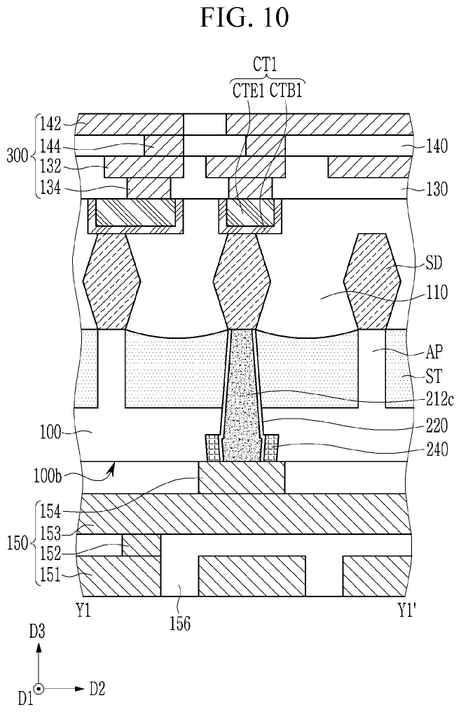

FIG. 10 illustrates a cross-sectional view of a semiconductor device according to an embodiment, and illustrates a cross-sectional view taken along line Y1-Y1′ of FIG. 1.

The embodiment shown in FIG. 10 has considerably the same portions as the embodiment shown in FIG. 7, so a description thereof will be omitted and differences will be mainly described. As detailed below, the embodiment of FIG. 10 is different from the embodiment of FIG. 7 in that the second portion of the through via itself forms the through via and the resulting through via directly contacts the source/drain patterns SD.

Referring to FIG. 10, the through via may be disposed immediately below at least some of the source/drain patterns SD, and the basic structure of the through via may be substantially the same as the second portion 212a of the through via in the embodiment of FIG. 7. However, in the embodiment shown in FIG. 10, the through via does not include a first portion and only includes a second portion 212c. The second portion 212c of the through via may contact the lower surface of the source/drain patterns SD to be electrically connected thereto. As a result, the second portion 212c in the embodiment shown in FIG. 10 may also be referred to herein as a “through via.” A metal silicide film (not shown) may be further disposed between the through via 212c and the source/drain patterns SD.

In this way, when the through via 212c is directly connected to the source/drain patterns SD, the disposition of the upper wire structure 300 or the first contact electrode CT1 may be simplified.

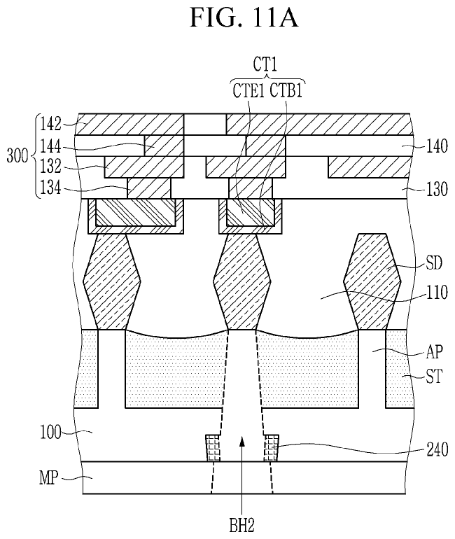

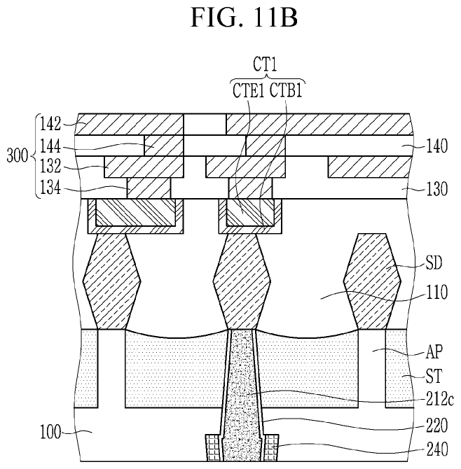

FIG. 11A and FIG. 11B are cross-sectional views sequentially illustrating a method of manufacturing the semiconductor device according to the embodiment of FIG. 10.

By applying the processes of FIG. 8A to FIG. 8H described above, the alignment pattern 240 and the sacrificial layer 401 may be formed in the semiconductor substrate 100, and the active patterns AP, the channel patterns, the gate structure, source/drain patterns SD, the device separation film ST, the first interlayer insulating layer 110, the first contact electrode CT1, and the upper wire structure 300 may be formed on the semiconductor substrate 100. A difference from FIG. 8A to FIG. 8H is that at least some of the source/drain patterns SD are disposed directly on the alignment pattern 240 and the first portion 211 of the through via is not formed. For example, the alignment pattern 240 may be aligned (e.g., in the third direction D3) with at least a portion of the source/drain patterns SD. In some embodiments, the second interlayer insulating layer may be additionally formed on the first interlayer insulating layer 110.

Next, referring to FIG. 11A, the etching mask pattern MP may be formed, and the second rear hole BH2 may be formed by etching the sacrificial layer 401, the semiconductor substrate 100, and the device separation layer ST inside the alignment pattern 240. In some embodiments, the sacrificial layer 401 may be removed before the etching mask pattern MP is formed. Through the second rear hole BH2, the bottom surface of at least some of the source/drain patterns SD may be exposed. This process may be performed in a state in which a carrier substrate (not shown) is attached on the upper wire structure 300 and the entire structure is turned over so that the rear surface of the semiconductor substrate 100 faces upward.

Referring to FIG. 11B, the side insulating film 220 may be formed on the side surface of the second rear hole BH2, and the through via 212c filling the second rear hole BH2 may be formed. The side insulating film 220 may be formed through insulating film deposition and anisotropic etching.

Subsequently, referring to FIG. 10, the lower wire structure 150 may be formed on the rear surface of the semiconductor substrate 100.

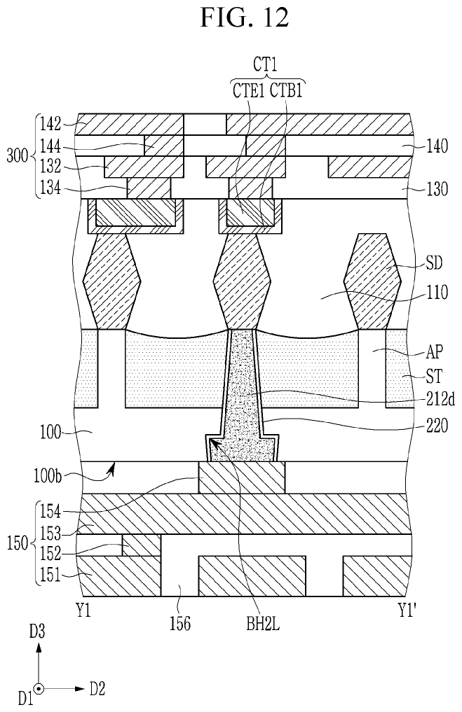

FIG. 12 illustrates a cross-sectional view of a semiconductor device according to another embodiment.

The embodiment of FIG. 12 is different from the embodiment of FIG. 10 in that the alignment pattern 240 is removed and the lower end portion BH2L of the second rear hole BH2 is extended, the side insulating film 220 is also formed on the side and bottom surfaces of the lower end BH2L of the second rear hole BH2, which is extended by removing the alignment pattern 240, and a second portion 212d of the through via fills the portion in which the alignment pattern 240 is removed. Accordingly, in the second portion 212d of the through via, a step may be formed between the lower end portion and the remaining portion thereon, and the side slope of the lower end portion may be different from that of the remaining portion. In the embodiment shown in FIG. 12, similar to the embodiment of FIG. 10, the through via does not include a first portion and only includes the second portion 212d. The second portion 212d of the through via may contact the lower surface of the source/drain patterns SD to be electrically connected thereto. As a result, the second portion 212d in the embodiment shown in FIG. 12 may also be referred to herein as a “through via.”

This structure may be implemented, after the step of FIG. 11A, by removing the alignment pattern 240 and forming the side insulating film 220 and the through via 212d. The alignment pattern 240 may be removed before or after the etching mask pattern MP is removed, and the removing of the alignment pattern 240 may be performed through an etching method having etching selectivity with respect to the alignment pattern 240.

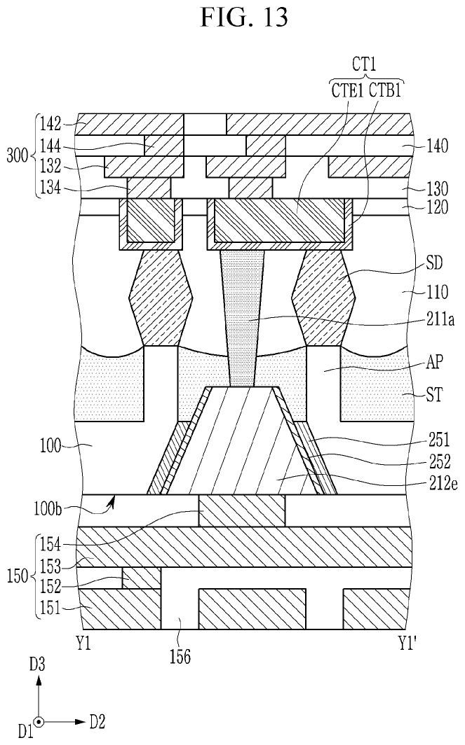

FIG. 13 illustrates a cross-sectional view of a semiconductor device according to an embodiment, and illustrates a cross-sectional view taken along line Y1-Y1′ of FIG. 1.

The embodiment of FIG. 13 differs from the embodiment of FIG. 7 in that the first and second side insulating films 251 and 252 are disposed on the side surface of second portion 212e of the through via. The first side insulating film 251 may be regarded as an alignment pattern that passes through the semiconductor substrate 100 to surround the through via. The first side insulating film 251 may contact the second side insulating film 252, and the second insulating film 252 may contact the second portion 212e of the through via.

Referring to FIG. 13, the second portion 212e of the through via penetrating the semiconductor substrate 100 and a portion of the device separation film ST may be disposed. The upper surface of the second portion 212e of the through via may contact the bottom surface of the first portion 211a. The side surface of the second portion 212e may be entirely covered by the second side insulating film 252, and the first side insulating film 251 may be disposed between the second side insulating film 252 and the semiconductor substrate 100.

As described above, insulation between the through via and the semiconductor substrate 100 may be ensured by disposing a double layer of side insulating film.

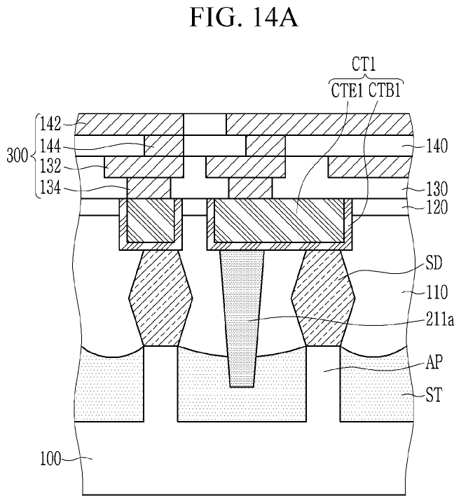

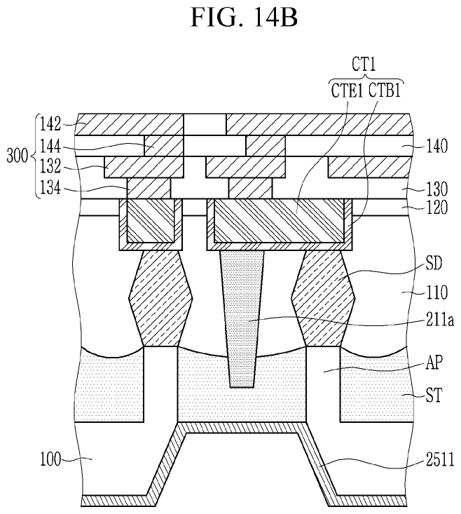

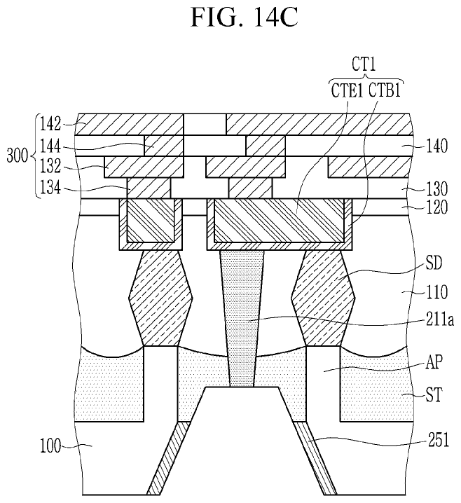

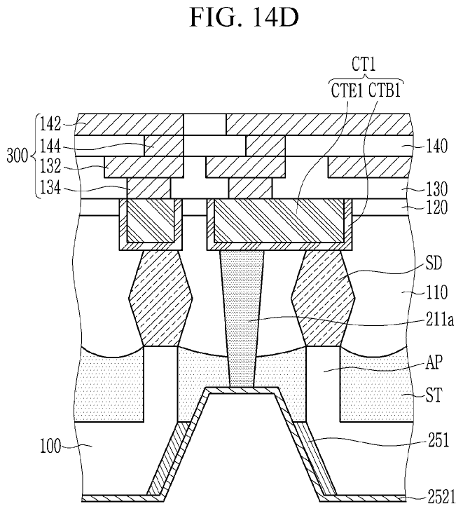

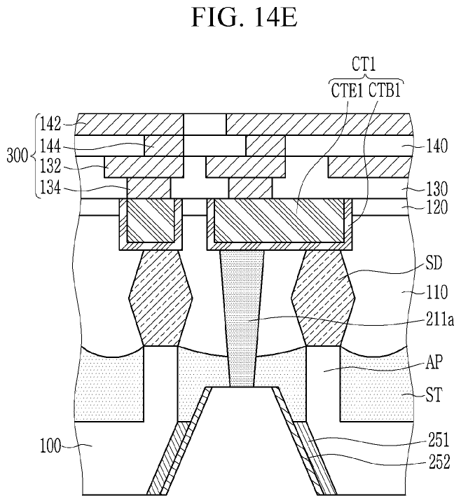

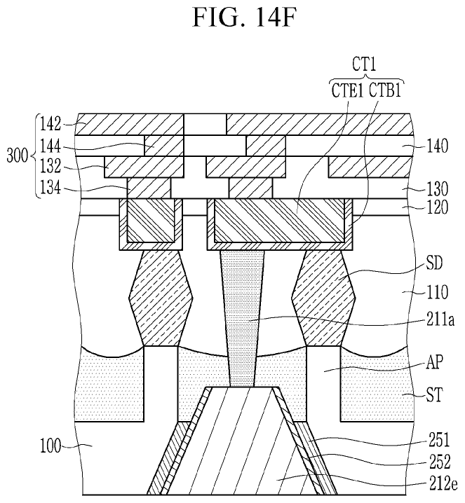

FIG. 14A to FIG. 14F are cross-sectional views sequentially illustrating a method of manufacturing the semiconductor device according to the embodiment of FIG. 13.

Referring to FIG. 14A, the active patterns AP, the channel patterns, the gate structure, the source/drain patterns SD, the device separation film ST, the first interlayer insulating layer 110, the second interlayer insulating film 120, the first portion 211a of the through via, the first contact electrode CT1, and the upper wire structure 300 may be formed on the semiconductor substrate 100.

Referring to FIG. 14B, a through hole passing through the semiconductor substrate 100 from the rear surface of the semiconductor substrate 100 may be formed, and a first preliminary side insulating film 2511 may be formed on the rear surface of the semiconductor substrate 100 and the entire inner surface of the through hole. This process may be performed in a state in which a carrier substrate (not shown) is attached on the upper wire structure 300 and the entire structure is turned over so that the rear surface of the semiconductor substrate 100 faces upward.

Referring to FIG. 14C, the first preliminary side insulating film 2511 may be anisotropically etched to form the first side insulating film 251, and the device separation film ST may also be etched to form the through hole exposing the bottom surface of the first portion 211 of the through via.

Referring to FIG. 14D, a second preliminary side insulating film 2521 may be formed on the entire inner surface of the through hole exposing the rear surface of the semiconductor substrate 10 and the lower portion of the first portion 211a.

Referring to FIG. 14E, the second preliminary side insulating film 2521 may be anisotropically etched to form the second side insulating film 252. Since the second side insulating film covers the side surface of the through hole, the lower portion of the first portion 211a may be exposed through the bottom of the through hole.

Referring to FIG. 14F, the through via may be completed by forming the second portion 212e filling the through hole.

Subsequently, referring to FIG. 13, the lower wire structure 150 may be formed on the rear surface of the semiconductor substrate 100.

As described above, double forming the side insulating films in separate processes may ensure the insulation between the through vias and the semiconductor substrate 100, and increase the misalignment tolerance of the through via formation.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

### DESCRIPTION OF SYMBOLS

100: semiconductor substrate
AP: active patterns
CH: channel patterns
GS: gate structure
SD: source/drain patterns
CT1, CT1′: first contact electrode
150: lower wire structure
300: upper wire structure
210: through via
211: first portion
212: Second portion
231: first etch stop film
232: second etch stop film
220: side insulating film
240: alignment pattern
401: sacrificial layer

What is claimed is:

1. A semiconductor device comprising:
a semiconductor substrate having first and second surfaces opposite each other;
a channel pattern disposed on the first surface of the semiconductor substrate;
source/drain patterns disposed on the first surface of the semiconductor substrate and disposed at both sides of the channel pattern;
first and second etch stop films disposed on the first surface of the semiconductor substrate;
a contact electrode electrically connected to the source/drain patterns;
a lower wire structure disposed on the second surface of the semiconductor substrate; and
a through via that passes through the semiconductor substrate, the first etch stop film, and the second etch stop film to connect the contact electrode and the lower wire structure,
wherein the through via includes
a first portion contacting the contact electrode and
a second portion contacting the first portion and disposed between the first portion and the lower wire structure.

2. The semiconductor device of claim 1, wherein
the first portion and the second portion contact each other at an interface between the first etch stop film and the second etch stop film.

3. The semiconductor device of claim 1, wherein
the first portion and the second portion contact each other on a surface of the second etch stop film.

4. The semiconductor device of claim 1, wherein
the first portion and the second portion contact each other at an interface between the first etch stop film and the semiconductor substrate.

5. The semiconductor device of claim 1, wherein
the first etch stop film includes a silicon oxide, and the second etch stop film includes at least one of a silicon nitride, a silicon oxynitride, a silicon carbonate nitride, a silicon boron nitride, a silicon carbon oxide, and a combination thereof.

6. The semiconductor device of claim 1, further comprising:
a device separation film disposed on the first surface of the semiconductor substrate,
wherein the first etch stop film and the second etch stop film are disposed between the device separation film and the semiconductor substrate.

7. The semiconductor device of claim 6, further comprising:
a gate structure surrounding the channel pattern;
an interlayer insulating film disposed on the device separation film; and
an upper wire structure disposed on the interlayer insulating film and electrically connected to the contact electrode.

8. The semiconductor device of claim 1, further comprising:
a side insulating film disposed between the second portion and the semiconductor substrate.

9. A semiconductor device comprising:
a semiconductor substrate having first and second surfaces opposite each other;
a channel pattern disposed on the first surface of the semiconductor substrate;
source/drain patterns disposed on the first surface of the semiconductor substrate and disposed at both sides of the channel pattern;
a lower wire structure disposed on the second surface of the semiconductor substrate;
a through via that passes through the semiconductor substrate and electrically connects the lower wire structure and the source/drain patterns; and
an alignment pattern exposed through the second surface of the semiconductor substrate and disposed at a perimeter of the through via.

10. The semiconductor device of claim 9, further comprising:
a contact electrode electrically connected to the source/drain patterns,
wherein the through via includes
a first portion contacting the through via, and
a second portion contacting the first portion and disposed between the first portion and the lower wire structure.

11. The semiconductor device of claim 9, wherein
the through via directly connects the source/drain patterns and the lower wire structure.

12. The semiconductor device of claim 9, wherein
the alignment pattern is an insulator.

13. The semiconductor device of claim 9, wherein
the alignment pattern has a ring shape and is disposed between the semiconductor substrate and the through via.

14. The semiconductor device of claim 9, further comprising:
a side insulating film disposed between the through via and the semiconductor substrate.

15. The semiconductor device of claim 9, wherein
the alignment pattern is a first side insulating film that is disposed in the semiconductor substrate and surrounds the through via, and
a second side insulating film disposed between the alignment pattern and the through via is further included.

16. The semiconductor device of claim 15, further comprising:
a device separation film disposed on the first surface of the semiconductor substrate,
wherein the first side insulating film passes through only the semiconductor substrate, and the second side insulating film passes through the semiconductor substrate and at least a portion of the device separation film.

17. A manufacturing method of a semiconductor device, comprising:
forming a groove on a first surface of a first semiconductor substrate having the first surface and a second surface opposite each other;
forming an alignment pattern disposed on an inner side surface of the groove and a sacrificial layer filling an inside of the alignment pattern;
attaching a second semiconductor substrate to the first surface of the first semiconductor substrate;
forming a channel pattern, source/drain patterns, a gate structure, and an upper wire structure on the second semiconductor substrate;
removing a portion of the second surface of the first semiconductor substrate to expose the alignment pattern and the sacrificial layer;
removing the sacrificial layer to form a first hole;
forming a second hole by etching the second semiconductor substrate exposed through the first hole; and
forming at least a portion of a through via filling the second hole.

18. The manufacturing method of the semiconductor device of claim 17, wherein
a first portion of the through via, disposed at a position aligned with the alignment pattern, is formed on the second semiconductor substrate before the upper wire structure is formed, and
at least a portion of the through via filling the second hole contacts the first portion.

19. The manufacturing method of the semiconductor device of claim 17, wherein
the alignment pattern is aligned with at least a portion of the source/drain patterns, and at least a portion of the through via filling the second hole contacts at least a portion of the source/drain patterns.

20. The manufacturing method of the semiconductor device of claim 17, wherein
the alignment pattern is removed before at least a portion of the through via that fills the second hole is formed.
